(19) United States
(12) Patent Application Publication
(10) Pub. No.: US 2005/0077835 A1
(43) Pub. Date: Apr. 14, 2005

(54) Thermal conductive medium for display device, method of fabricating the same, and plasma display panel assembly using the same

(76) Inventor: Ki-Jung Kim, Cheonan-si (KR)

Correspondence Address: Robert E. Bushnell;Suite 300, 1522 K Street. N.W., Washington, DC, 20005-1202, US

(21) Appl. No.: 10/923,737

(22) Filed: Aug. 24, 2004

(30) Foreign Application Priority Data
Oct. 8, 2003 (KR) 2003-70045

(51) Int. Cl. G09G 3/10; H05K 7/20

(52) U.S. Cl. 315/169.4

(57) ABSTRACT

A plasma display panel assembly comprises: a panel assembly which includes a front panel and a rear panel for displaying an image in combination with the front panel; a chassis base joined to the panel assembly for conducting and dissipating heat generated in the panel assembly; a thermal conductivity medium formed of a heat radiation sheet made of a polymer resin for conducting and dissipating heat generated in the panel assembly, and a ceramic layer formed at least on a surface of the heat radiation sheet, and disposed between the panel assembly and the chassis base and joining the chassis base and the panel assembly; a circuit board joined to the chassis base, electronic parts being mounted on the circuit board for transmitting electrical signals to the panel assembly; and a case which accommodates the panel assembly, the chassis base, and the circuit board. Since the high thermal conductivity ceramic material rapidly conducts heat generated in the panel assembly, uniform heat dissipation from a large size panel assembly can be achieved, thereby reducing temperature difference in the panel assembly and solving a bright afterglow problem accompanied by increases in the brightness.

### CLAIM OF PRIORITY

This application makes reference to, incorporates the same herein, and claims all benefits accruing under 35 U.S.C. section 119 from an application for THERMAL CONDUCTIVE MEDIUM FOR DISPLAY DEVICE, METHOD OF FABRICATING THE SAME, AND PLASMA DISPLAY PANEL ASSEMBLY USING THE SAME earlier filed in the Korean Intellectual Property Office on Oct. 8, 2003 and there duly assigned Ser. No. 2003-70045.

### BACKGROUND OF THE INVENTION

1. Technical Field

The present invention relates to a plasma display panel assembly, and more particularly, to an improved thermal conductive medium disposed between a display panel and a chassis base, a method of fabricating the same, and a plasma display panel assembly using the same.

2. Description of the Related Art

A plasma display panel assembly is typically a flat display device which displays an image using light emitted by ultraviolet rays generated in a discharge space. The light is generated by discharging a discharge gas filling a space between substrates by applying a predetermined power to discharge electrodes formed on a plurality of substrates facing each other. The plasma display panel assembly can be manufactured to a thickness of less than a few centimeters, can be fabricated in the form of a large screen, and can have a viewing angle of more than 150°. Therefore, the flat display panel attracts attention as a display device for the next generation.

The plasma display panel assembly is fabricated such that a front panel and a rear panel are separately manufactured and combined, a chassis base is fabricated on a backside of the panels, a circuit board for electrical signal communication to the display panel is mounted on the chassis base, a predetermined inspection is performed, and the display panel is mounted in a cabinet.

U.S. Pat. No. 5,971,566 to Tani et al., entitled PLASMA DISPLAY DEVICE AND ITS MANUFACTURING METHOD, issued on Oct. 26, 1999 is considered to be generally pertinent to the present invention, but is burdened by the disadvantages set forth below.

A plasma display panel assembly comprises a front panel, a rear panel which is combined with the front panel, and a chassis base which is combined with a rear side of the rear panel. A thermal conductive medium is disposed between the rear panel and the chassis base.

The thermal conductive medium has a double layer structure which includes a first thermal conductive medium attached to a rear side of the rear panel and a second thermal conductive medium attached to an upper surface of the first thermal conductive medium. The first thermal conductive medium is formed of a material having a thermal conductivity higher than that of the second thermal conductive medium.

The above configuration of a thermal conductive medium has disadvantages in that heat generated in the panel cannot be effectively conducted because of a low thermal transfer coefficient of the thermal conductive medium, and the manufacturing processes are complicated because the first and second thermal conductive media are separately manufactured, thereby increasing the manufacturing cost.

A thermal conductive medium is formed of graphite sheets made of graphite powder by compression, and each location is fixed by adhesive, there being a higher heat radiation characteristic in a direction of the panel plane since graphite has a high thermal transfer coefficient close to 200 W/mK.

However, the thermal conductive medium may bent or broken by its weight if it is formed in a single sheet when disposing it between the panel and the chassis base. Manufacturing the thermal conductive medium is not easy because the sheet is formed of graphite molecules having a weak bonding force, and a finger is smeared with graphite. Graphite is more expensive than silicon sheet, which is one of the substitutes for graphite.

The silicon sheet is not bent or broken as graphite sheet is since silicon is a soft material, but it causes a regional temperature difference due to low thermal conductivity. Therefore, there is a bright afterglow problem due to increased brightness of the panel.

### SUMMARY OF THE INVENTION

To solve the above and other problems, the present invention provides a thermal conductivity medium for a display device, a method of manufacturing the same, and a plasma display panel assembly to which the thermal conductivity medium is applied. The thermal conductivity medium can reduce a temperature difference in the panel due to coating of a high thermal conductive ceramic material on a surface of the thermal conductivity medium that contacts a heat generating part of the panel assembly.

According to an embodiment of the present invention, there is provided a thermal conductivity medium for a display device, the thermal conductivity medium being disposed between a panel assembly that generates heat during operation and a chassis base that conducts heat. The thermal conductivity medium comprises a heat radiation sheet formed of a polymer resin, and a ceramic layer that conducts heat formed on a surface of the heat radiation sheet and contacting a rear side of the panel assembly.

According to an embodiment of the present invention, there is provided a method of manufacturing a thermal conductivity medium for a display panel, the thermal conductivity medium being disposed between a panel assembly that generates heat during operation and a chassis base that conducts heat, the method comprising preparing a ceramic layer that conducts heat, contacting a rear of the panel assembly with the ceramic layer, preparing a heat radiation sheet made of a polymer resin, and joining the ceramic layer to a surface of the heat radiation sheet.

According to an embodiment of the present invention, there is provided a plasma display panel assembly to which the thermal conductivity medium is applied, the panel assembly comprising: a panel assembly that includes a front panel and a rear panel which displays an image in combination with the front panel; a chassis base that dissipates heat generated in the panel assembly, the chassis base being combined with the panel assembly; a thermal conductivity medium formed of a heat radiation sheet which is composed of a polymer resin for conducting heat generated from the panel assembly and a ceramic layer which is formed at least on a surface of the heat radiation sheet, the medium being disposed between the panel assembly and the chassis base, the chassis base being combined with the panel assembly; a circuit board combined with the chassis base, electronic parts for transmitting electrical signals to the panel assembly being mounted on the circuit board; and a case that accommodates the panel assembly, the chassis base and the circuit board.

### BRIEF DESCRIPTION OF THE DRAWINGS

A more complicated appreciation of invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view of a plasma display panel assembly;

FIG. 2 is a cross-sectional view of a thermal conductive medium;

FIG. 3 is a partial exploded perspective view of a plasma display panel assembly according to an embodiment of the present invention;

FIG. 4 is a cross-sectional view of a thermal conductive medium used in the plasma display panel assembly of FIG. 3 according to the present invention;

FIG. 5 is a cross-sectional view illustrating a first step of a first method of manufacturing a thermal conductive medium according to the present invention;

FIG. 6 is a cross-sectional view illustrating a second step of the first method of manufacturing a thermal conductive medium according to the present invention;

FIG. 7 is a cross-sectional view illustrating a third step of the first method of manufacturing a thermal conductive medium according to the present invention;

FIG. 8 is a cross-sectional view illustrating a second method of manufacturing a thermal conductive medium according to the present invention; and

FIG. 9 is a cross-sectional view showing the thermal conductive medium of the present invention disposed between a panel and a chassis base.

### DETAILED DESCRIPTION OF THE INVENTION

Hereinafter, a plasma display panel assembly according to embodiments of the present invention will be described more fully with reference to the accompanying drawings.

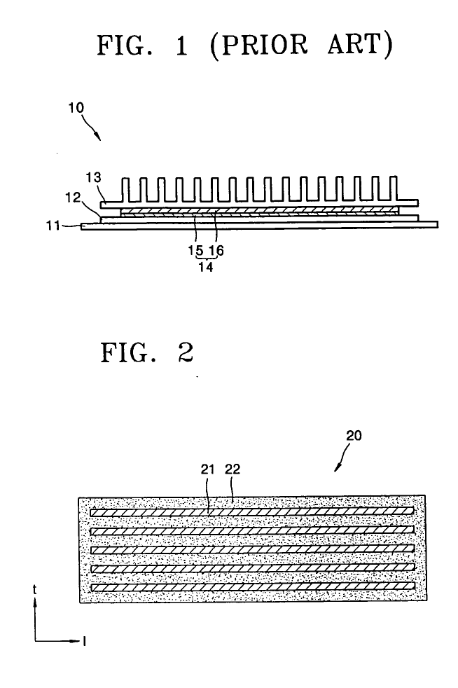

FIG. 1 is a cross-sectional view of a plasma display panel assembly.

Referring to FIG. 1, the plasma display panel assembly 10 comprises a front panel 11, a rear panel 12 which is combined with the front panel 11, and a chassis base 13 which is combined with a rear side of the rear panel 12. A thermal conductive medium 14 is disposed between the rear panel 12 and the chassis base 13.

The thermal conductive medium 14 has a double layer structure which includes a first thermal conductive medium 15 attached to a rear side of the rear panel 12 and a second thermal conductive medium 16 attached to an upper surface of the first thermal conductive medium 15. The first thermal conductive medium 15 is formed of a material having a thermal conductivity higher than that of the second thermal conductive medium 16.

The above configuration of a thermal conductive medium 14 has disadvantages in that heat generated in the panel 12 cannot be effectively conducted because of a low thermal transfer coefficient of the thermal conductive medium 14, and the manufacturing processes are complicated because the first and second thermal conductive media 15 and 16, respectively, are separately manufactured, thereby increasing the manufacturing cost.

FIG. 2 is a cross-sectional view of a thermal conductive medium. Referring to FIG. 2, the thermal conductive medium 20 is formed of graphite sheets 21 made of graphite powder by compression, and each location is fixed by adhesive 22, there being a higher heat radiation characteristic in a direction of the panel plane since graphite has a high thermal transfer coefficient close to 200 W/mK.

However, the thermal conductive medium 20 may be bent or broken by its weight if it is formed in a single sheet when disposing it between the panel and the chassis base. Manufacturing the thermal conductive medium 20 is not easy because the sheet is formed of graphite molecules having a weak bonding force, and a finger is smeared with graphite. Graphite is more expensive than silicon sheet, which is one of the substitutes for graphite.

The silicon sheet is not bent or broken as graphite sheet is since silicon is a soft material, but it causes a regional temperature difference due to low thermal conductivity. Therefore, there is a bright afterglow problem due to increased brightness of the panel.

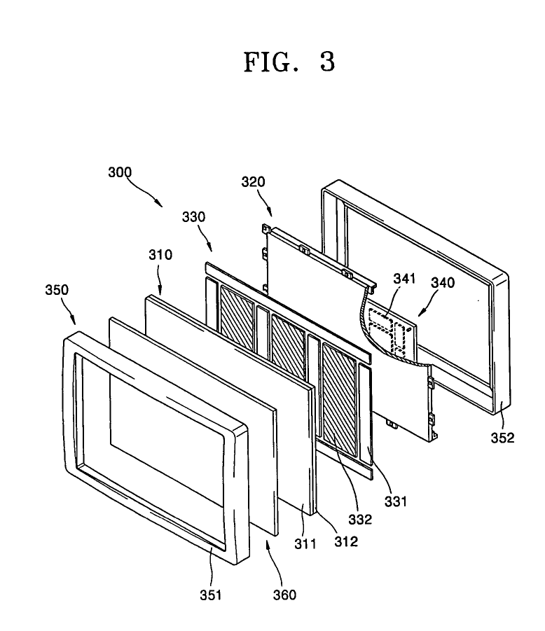

FIG. 3 is a partial exploded perspective view of a plasma display panel assembly according to an embodiment of the present invention.

Referring to FIG. 3, the plasma display panel assembly 300 comprises a panel assembly 310, a chassis base 320 which supports the panel assembly 310, an adhesive member 330 which fixes the panel assembly 310 to the chassis base 320, a circuit board 340 mounted on a rear side of the chassis base 320, and a case 350 which accommodates the panel assembly 310, the chassis base 320, and the circuit board 340.

The panel assembly 310 includes a front panel 311 and a rear panel 312.

The front panel 311 includes X and Y electrodes, a bus electrode electrically connected to the X and Y electrodes, a front dielectric layer which covers the X and Y electrodes and the bus electrode, and a protective layer which is coated on a surface of the front dielectric layer.

The rear panel 312 faces the front panel 311, and includes an address electrode, a rear dielectric layer which covers the address electrode, barrier ribs that define a discharge space and prevent cross talk, and red, green and blue color fluorescent layers that coat inner sides of the barrier ribs.

The chassis base 320 is disposed behind, and supports, the panel assembly 310.

The adhesive member 330 is disposed between the chassis base 320 and the panel assembly 310, and fixes the chassis base 320 to the panel assembly 310. The adhesive member 330 includes double-sided adhesive 331 and a thermal conductive medium 332 for dissipating heat generated in the panel assembly 310 through the chassis base 320.

The circuit board 340 is disposed on a rear side of the chassis base 320, and includes a plurality of electronic parts for communicating electrical signals to each electrode terminal of the panel assembly 310.

The case 350 includes a front cabinet 351 disposed in front of the panel assembly 310 and a rear cover 352 attached to a rear side of the chassis base 320 opposite to the circuit board 340, and accommodates the panel assembly 310 and the chassis base 320 joined together by the adhesive member 330.

A filter assembly 360 is installed in front of the panel assembly 310 for shielding electromagnetic waves, infrared rays, and neon light generated by the panel, or the reflection of external light.

The filter assembly 360 comprises: a transparent substrate on which an anti-reflection film is attached so as to prevent a lowering of visibility by reflection of external light; an electromagnetic wave shielding layer for shielding electromagnetic waves generated during panel operation; and a selective wave absorption film for shielding unnecessary emission of near infrared rays by plasma generated from an inert gas used for emitting light for image display.

According to an embodiment of the present invention, a ceramic material is added to the thermal conductive medium 332 to simultaneously improve adhesion and thermal conductivity.

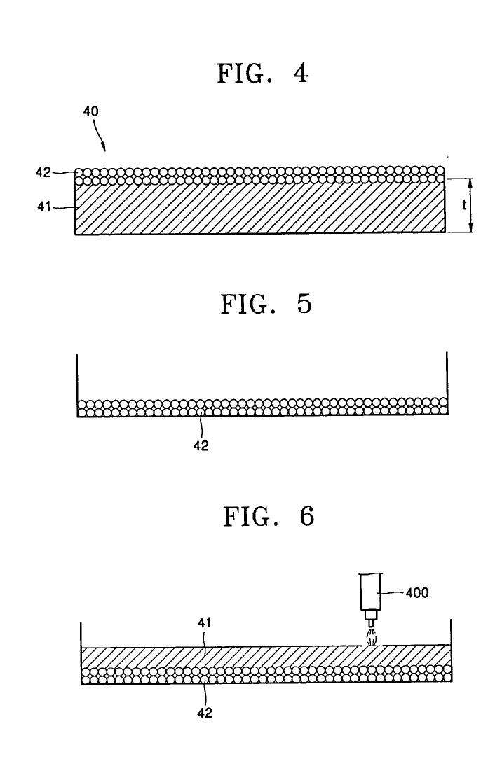

FIG. 4 is a cross-sectional view of a thermal conductive medium used in the plasma display panel assembly of FIG. 3 according to the present invention.

Referring to FIG. 4, the thermal conductive medium 40 is formed of a polymer resin that does not bend or break since it is soft, for example, a heat radiation sheet such as a silicon sheet 41. A urethane sheet or an acryl sheet can also be used. The silicon sheet 41 can increase adhesion of the chassis base 320 (FIG. 3) to the panel assembly 310. The thickness t (FIG. 4) of the silicon sheet 41 can be approximately 1˜2 mm, preferably, 1.5 mm.

A ceramic layer 42, such as alumina (Al₂O₃), having a high thermal conductivity, is coated on a surface of the silicon sheet 41. The ceramic layer 42 is formed of ceramic powder having a ball shape. The diameter of the ceramic powder is about 100˜500 μm.

The surface of the silicon sheet 41 coated with the ceramic layer 42 is connected to an electronic device that generates heat, and the other surface of the silicon sheet 41 is not coated with a ceramic layer 42 and is connected to a heat radiation means for dissipating heat.

The thermal conductive medium 40 having the above structure can be manufactured by several methods. FIGS. 5 thru 7 illustrate a first method of manufacturing a thermal conductive medium according to the present invention.

As depicted in FIGS. 5 thru 7, the first method comprises formation of the ceramic layer 42 using ceramic powder having a ball shape (FIG. 5), followed by spraying of liquid silicon 41 onto the ceramic layer 42 using a nozzle 400, and then drying at a predetermined temperature.

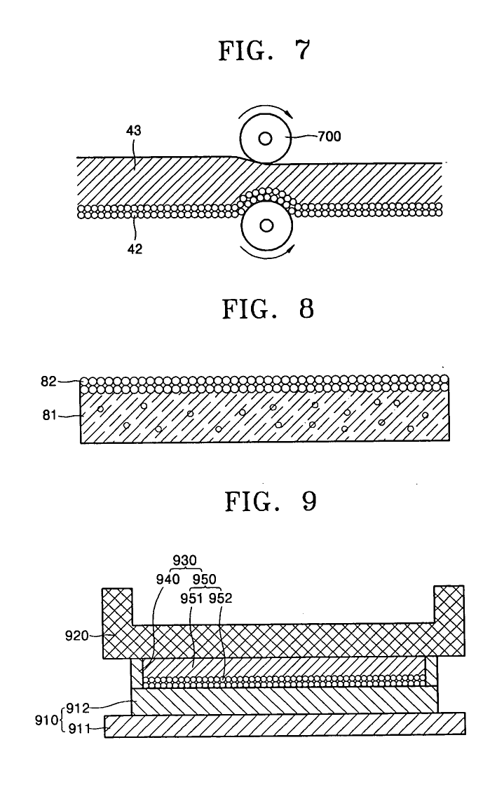

Next, the silicon sheet 41 on which the ceramic layer 42 is formed is passed through two rollers 700 (FIG. 7) to which a predetermined pressure and heat are applied. Then, a thermal conductive medium 40 formed of silicon sheet 41 having a desired thickness, with the ceramic layer 42 fixed tightly thereto, is manufactured.

FIG. 8 is a cross-sectional view illustrating a second method of manufacturing a thermal conductive medium according to the present invention.

Referring to FIG. 8, a ceramic layer 82 is formed on a surface of the silicon sheet 81, and a ceramic powder is then dispersed in the silicon sheet 81 to improve heat dissipation in the silicon sheet 81.

FIG. 9 is a cross-sectional view showing the thermal conductive medium of the present invention disposed between a panel assembly and a chassis base.

Referring to FIG. 9, the panel assembly 910 includes a front panel 911 and a rear panel 912 for realizing an image with the front panel 911. A chassis base 920 is disposed behind the panel assembly 910, and supports the panel assembly 910.

An adhesive member 930 is disposed between the panel assembly 910 and the chassis base 920 for dissipating heat generated in the panel assembly 910 during operation, and for fixing the chassis base 920 to the panel assembly 910.

A double-sided adhesive 940 for joining the chassis base 920 to the panel assembly 910 is disposed on edges of contacting surfaces therebetween.

A thermal conductive medium 950 according to the present invention is attached to the surfaces between the panel assembly 910 and the chassis base 920 in areas where the double-sided adhesive 940 is not attached.

The thermal conductive medium 950 is formed of a silicon sheet 951 which has high adhesion capability, and a ceramic layer 952 which has high thermal conductivity (for example, alumina) is coated on a surface of the silicon sheet 951.

The surface of silicon sheet 951 on which ceramic layer 952 is coated is attached to a rear side of the panel assembly 910, which generates heat during operation, and the other surface of the silicon sheet 951 (on which the ceramic layer 952 is not coated) is attached to the chassis base 920.

Because the silicon sheet 951 coated with a ceramic layer 952 having a high thermal conductivity is interposed between the panel assembly 910 and the chassis base 920, heat generated in the panel assembly 910 is rapidly conducted and dissipated.

As described above, the thermal conductivity medium for a display device, the method of manufacturing, and the display plasma panel assembly according to the present invention provide the following advantages.

First, since the thermal conductivity medium 950 disposed between the plasma display panel assembly 910 and the chassis base 920 has the double layer structure of silicon sheet 951 coated with a ceramic layer 952, heat generated in the panel assembly 910 is quickly conducted through the chassis base 920. The thermal conductivity medium 950 has a high adhesion capability.

Second, since heat generated in the panel assembly 910 can be quickly conducted and dissipated by the high thermal conductivity ceramic layer 952, uniform heat dissipation from a large size panel assembly can be achieved. Accordingly, the temperature difference between regions in the panel can be reduced, thereby removing a bright afterglow problem.

Third, workability can be improved since a finger tip is not smeared with material dust of the thermal conductivity medium during manufacturing because the thermal conductivity medium has a structure of silicon sheet coated with a ceramic layer.

Fourth, the manufacturing cost can be reduced due to the use of a soft silicon sheet.

While this invention has been particularly shown and described with reference to preferred embodiments thereof, it will be understood by those skilled in the art that various changes in form and details may be made therein without departing from the spirit and scope of the invention as defined by the appended claims.

1. A thermal conductivity medium for use in a display device which in includes a panel assembly which generates heat during operation and a chassis base which conducts heat, said thermal conductivity medium comprising:
a heat radiation sheet formed of a polymer resin and disposed adjacent to the chassis base; and
a ceramic layer disposed between the heat radiation sheet and a rear side of the panel assembly for conducting heat from the panel assembly to the heat radiation sheet, whereby the heat radiation sheet dissipates the heat through the chassis base.

2. The thermal conductivity medium of claim 1, wherein the heat radiation sheet is a silicon sheet.

3. The thermal conductivity medium of claim 2, wherein a thickness of the heat radiation sheet is in a range of 1˜2 mm.

4. The thermal conductivity medium of claim 1, wherein the ceramic layer is formed of alumina.

5. The thermal conductivity medium of claim 4, wherein the alumina is alumina powder formed in a ball shape.

6. The thermal conductivity medium of claim 5, wherein a diameter of the alumina powder is in a range of 100˜500 μm.

7. A method of manufacturing a thermal conductivity medium for a display panel, the method comprising the steps of:
(a) preparing a ceramic material which conducts heat;
(b) preparing a heat radiation sheet made of a polymer resin; and
(c) disposing the ceramic material on a surface of the heat radiation sheet.

8. The method of claim 7, wherein step (a) comprises preparing a liquid ceramic material, and step (c) comprises spraying the liquid ceramic material on the surface of the heat radiation sheet.

9. The method of claim 7, wherein step (a) comprises preparing a powered ceramic material having a ball shape, and step (c) comprises coating the surface of the heat radiation sheet with the powdered ceramic material.

10. The method of claim 8, wherein step (c) further comprises passing the heat radiation sheet with the powdered ceramic material between two rollers to which a predetermined temperature and pressure are applied.

11. The method of claim 10, wherein the heat radiation sheet is in a gel state.

12. The method of claim 9, wherein the heat radiation sheet is in a gel state.

13. The method of claim 7, wherein the ceramic material is disposed on a surface of, and in, the heat radiation sheet.

14. A plasma display panel assembly, comprising:
a panel assembly which includes a front panel and a rear panel for displaying an image in combination with the front panel;
a chassis base which dissipates heat generated in the panel assembly;
a thermal conductivity medium disposed between the panel assembly and the chassis base, and joining the panel assembly to the chassis base, said thermal conductivity medium comprising a heat radiation sheet made of a polymer resin for conducting heat generated in the panel assembly and a ceramic layer formed on a surface of the heat radiation sheet;
a circuit board joined to the chassis base and including electronic parts for transmitting electrical signals to the panel assembly; and
a case for accommodating the panel assembly, the chassis base and the circuit board.

15. The plasma display panel assembly of claim 14, wherein the surface of the heat radiation sheet on which the ceramic layer is formed contacts a rear side of the panel assembly.

16. The plasma display panel assembly of claim 14, wherein the heat radiation sheet is a silicon sheet.

17. The plasma display panel assembly of claim 16, wherein a thickness of the heat radiation sheet is in a range of 1˜2 mm.

18. The plasma display panel assembly of claim 14, wherein the ceramic layer is formed of alumina.

19. The plasma display panel assembly of claim 18, wherein the alumina is powder formed in a ball shape.

20. The plasma display panel assembly of claim 19, wherein a diameter of the alumina powder is in a range of 100˜500 μm.

21. The plasma display panel assembly of claim 14, wherein the heat radiation sheet is formed of a polymer resin.
